(19) United States
(12) Patent Application Publication
(10) Pub. No.: US 2010/0173153 A1
(43) Pub. Date: Jul. 8, 2010

(54) BEAM-LIKE MATERIAL COMPRISING CARBON NANOTUBE AND MANUFACTURING METHOD THEREOF

(76) Inventors: Kenji Hata, Ibaraki (JP); Yuhei Hayamizu, Ibaraki (JP)

Correspondence Address: WENDEROTH, LIND & PONACK, L.L.P., 1030 15th Street, N.W.,, Suite 400 East, Washington, DC, 20005-1503, US

(21) Appl. No.: 12/449,664

(22) PCT Filed: Feb. 20, 2008
(86) PCT No.: PCT/JP2008/052875

§ 371 Date: Jan. 22, 2010

(30) Foreign Application Priority Data
Feb. 20, 2007 (JP) 207-039531

(51) Int. Cl. B32B 5/16; C23C 16/26

(52) U.S. Cl. 428/367; 427/249.1; 977/843; 977/742

(57) ABSTRACT

A beam-like material 1, 11 is formed of a CNT aggregate 25 comprising a plurality of CNTs aligned in the same direction and having a weight density of from 0.1 to 1.5 g/cm³, thereby providing a beam-like material comprising a CNT aggregate having anisotropy and shape restorability and capable of being formed to a desired shape at a desired position.

### TECHNICAL FIELD

The present invention relates to a beam-like material comprising carbon nanotubes and a manufacturing method thereof. More specifically, the invention relates to a beam-like material comprising carbon nanotubes having anisotropy and shape-restoring property and capable of being formed to a desired shape at a desired position, and a manufacturing method thereof.

### BACKGROUND ART

Application of carbon nanotubes (hereinafter also referred to as CNTs) as a constituent material for devices of micromachines (MEMS) has tended to be increased in the field of nanotechnology. For example, utilization of CNTs to beam-like material is expected for supporting movable contacts of probes for sensors and switching devices such as relays and memories. In the present invention, “beam-like material” means an elongate rod-like structural material in which at least one end is extended from the surface or the wall surface of a substrate or a base block in a horizontal direction or in a direction approximate thereto.

For such a beam-like material, there have been known an example of using a single or plural CNTs (Patent Document 1) or a technique of manufacturing a device for MEMS by coating a liquid suspension formed by dispersing CNTs in a solvent to a groove on a substrate or a mold formed by patterning, and removing the mold after evaporation of the solvent (Patent Document 2).

Patent Document 1: JP-A-2006-228818

Patent Document 2: JP-A-2007-63116

### DISCLOSURE OF THE INVENTION

### Problems that the Invention is to Solve

The example described in the Patent Document 1 cannot arbitrary set the shape, as well as a technical idea of using a plurality of CNTs aggregated is not found therein as apparent in that prevention of bundling is not intended (column 0048). Referring more specifically, for conforming a beam-like material comprising CNTs to a device used for MEMS, it is indispensable to manufacture a beam-like material with arbitrary controlled physical properties such as electric properties (for example, electric conductivity), optical properties (for example, transmittance), or mechanical properties (for example, bending property). However, such physical properties depend on the shape thereof. In this regard, according to the technique described in the Patent Document 1, the CNT beam-like material cannot be formed to a desired shape at a desired position as described above and, particularly, it is difficult to obtain a shape restorability of restoring to an original position when an external force or an electric current is removed.

On the other hand, while a CNT aggregate in which a plurality of CNTs are aligned in one identical direction can be provided with a property that is different between the direction of alignment and the direction perpendicular thereto, that is, anisotropy for the physical property, it is difficult to provide the anisotropy for those described in the Patent document 2 in view of the manufacturing method thereof. Further, when a plurality of CNTs are aligned at random, since the plurality of CNTs cannot be filled uniformly with no gaps, it is difficult by those described in the Patent document 2 to obtain a CNT layer at a high density having a desired mechanical strength.

That is, according to the prior art, it was extremely difficult to form a beam-like material having the anisotropy and the shape restorability to a desired shape at a desired position by using the CNT aggregate and a beam-like material comprising CNTs having controlled and stable physical property could not be manufactured at a good yield. In the specification, the CNT aggregate means a structural body in which a plurality of CNTs (for example, at a number density of 5×11¹¹ N/cm² or more) are gathered in a layered or bundled form.

The invention has been achieved in view of such a situation in the prior art and it is an object thereof to provide a beam-like material comprising a CNT aggregate having the anisotropy and the shape restorability and capable of being formed to a desired shape at a desired position.

### Means for Solving the Problems

For solving the subject, the following inventions are provided.

[1] A beam-like material 1, 11 is formed of a CNT aggregate 25 comprising a plurality of CNTs aligned in the same direction and having a weight density of from 0.1 to 1.5 g/cm³ and, more preferably, from 0.2 to 1.5 g/cm³. With such a constitution, a beam-like material having anisotropy and shape restorability can be obtained (FIG. 1, FIG. 2). Referring more specifically, a plurality of CNTs aligned in the same direction can be easily filled uniformly and with no gaps. Such a CNT aggregate having the plurality of CNTs bonded intensely to each other by Van der Waals' force to a high density forms a so-called solid material having integrity and shape retainability and is provided with physical properties necessary for devices used for MEMS, etc. Accordingly, it may suffice that the alignment of the CNTs required for the CNT aggregate is at such an extent that a density-increasing step can be practiced, and the integrity, the shape retainability and the shape fabricability of the CNT aggregate are permitted in view of practical use of the device used for MEMS, etc. and this is not necessarily complete.
[2] A manufacturing method of a beam-like material comprising a plurality of CNTs includes a chemical vapor deposition step S1 of forming a pattern of a metal catalyst on the surface and growning the plurality of CNTs by chemical vapor deposition in the same direction from the pattern of the metal catalyst, a turn-down step S2 of turning down a CNT aggregate comprising the plurality of CNTs to the surface of the substrate, a density-increasing step S3 of increasing the density of the CNT aggregate turned down to the surface of the substrate such that the weight density is from 0.1 to 1.5 g/cm³ and, more preferably, from 0.2 to 1.5 g/cm³, and a removing step S4 of selectively removing an unnecessary portion of the density-increased CNT aggregate (FIG. 3). With such a constitution, since well-known patterning technique and etching technique are applicable, a beam-like material having anisotropy and shape restorability can be easily formed to a desired shape at a desired position.
[3] Particularly, the turn-down step is defined as a step of pulling up the CNT aggregate after dipping in a liquid thereby turning down the same to the surface of the substrate, and the density-increasing step is defined as a step of drying the CNT aggregate after the turn-down step. This can provide a CNT aggregate of uniformly increased density with no local stress concentration.
[4] A method of manufacturing a beam-like material comprising a plurality of CNTs includes a chemical vapor phase deposition step of forming a substrate with a metal catalyst film on the surface and growing a plurality of CNTs by chemical vapor deposition from the metal catalyst film in the same direction, a placing step of placing a CNT aggregate comprising a plurality of CNTs aligned in the same direction to the surface of a second substrate with the axis of alignment thereof being in parallel with the surface of the second substrate, a density-increasing step of increasing the density of the CNT aggregate placed on the surface of the second substrate such that the weight density thereof is from 0.1 to 1.5 g/cm³ and, more preferably, from 0.2 to 1.5 g/cm³ and a removing step of selectively removing an unnecessary portion of the density increased CNT aggregate. This enables easy formation of a beam-like material having anisotropy and shape restorability to a desired shape at a desired position, as well as the degree of freedom for the fabrication of a substrate to form a beam-like material is enhanced since a substrate for growing the CNT aggregate and the substrate for forming the beam-like material are different.
[5] Particularly, the density-increasing step is preferably defined as a step of exposing the CNT aggregate to a liquid and drying the same in a state being placed on the second substrate.

According to the invention adopting the technical means or the method as described above, a beam-like material formed of the CNT aggregate comprising the plurality of CNTs aligned in the same direction can be formed at a desired position. Further, since the CNT aggregate at high density can improve the shape retainability, the shape restorability is obtained, as well as a beam-like material of a desired shape can be formed easily since the well-known pattering technique and etching technique are applicable. Particularly, since the physical properties of the beam-like material depend on the shape, capability of forming a beam-like material of a desired shape means that a beam-like material having desired physical properties can be formed and the adaptability of the beam-like material to the device for use in MEMS, etc. is enhanced. That is, the invention can provide a significant effect for providing a beam-like material comprising the CNT aggregate having the anisotropy and the shape restorability and capable of being formed to a desired shape at a desired position.

### BRIEF DESCRIPTION OF THE DRAWINGS

FIG. 1 is a schematic cross sectional view showing the structure of a beam-like material according to an embodiment of the invention in which (a) shows a cantilever beam type and (b) shows a fixed-fixed beam type.

FIG. 2 is a schematic view showing an example of a method of manufacturing a beam-like material of the invention in which (a) is a plan view showing a state of forming a linear pattern of a metal catalyst on a grooved surface, (b) is a side elevational view showing a state of turning down a plurality of vertically aligned CNTs on a grooved substrate, (c) is a view showing the state of pulling up CNTs aligned vertically on the substrate after dipping the same in a liquid and (d) is a cross sectional view showing the state where a CNT layer is deposited over the grooved substrate.

FIG. 3 is a flow chart showing a schematic step in the method of manufacturing a product of the invention.

FIG. 4 is an electron microscope photographic image for a grooved surface deposited with a CNT layer.

FIG. 5 is an electron microscope photographic image showing a portion of a substrate shown in FIG. 4 in an enlarged scale.

FIG. 6 is a schematic structural view of a CVD apparatus used for manufacture in an example.

FIG. 7 is a scanning type atomic force microscope photographic image showing a portion of a surface of a density-increased CNT layer in an enlarged scale.

FIG. 8 is a measurement graph showing the anisotropy of optical transmittance of a CNT layer.

FIG. 9 is an electron microscope photographic image showing an example of a cantilever beam.

FIG. 10 is an electron microscope photographic image showing an example of a fixed-fixed beam.

FIG. 11 is a schematic view showing an example of a manufacturing method of forming a groove in a substrate and forming a beam-like material thereabove.

FIG. 12 is an electron microscope photographic image for a beam-like material manufactured by the manufacturing method shown in FIG. 11.

FIG. 13 is an optical microscope photographic image for a beam-like material manufactured by another manufacturing method.

FIG. 14 shows a horizontal operation type 2-terminal switch applied with the invention in which (a) is an electron microscope photographic image thereof, and (b) is a plan view.

FIG. 15 is a graph showing a relation between a resonance frequency and a length for each of beam-like materials having length different from each other. Further, the table shows a sonic velocity in the beam-like CNT material obtained by the measurement and a sonic velocity in the (111) direction of single crystal silicon reported so far. Further, two formulae are theoretical formulae showing a relation between the length and the resonance frequency of a cantilever beam and a fixed beam as an elastic body.

FIG. 16 is an electron microscope photographic image showing the state where a beam-like CNT material is displaced by the application of voltage.

FIG. 17 is an electron microscope photographic image showing the state of applying an external force on the beam-like CNT material.

FIG. 18 is a relational graph showing the change of thickness of a film-like CNT aggregate before and after the density-increasing step.

FIG. 19 is a relational graph for the thickness of a film-like CNT aggregate before the density-increasing step and the weight density of the film-like CNT aggregate after the density-increasing step.

FIG. 20 is a relational graph between the diameter and the weight density upon close packing of a CNT.

### DESCRIPTION OF THE REFERENCE NUMERALS AND SIGNS

1 cantilever beam
2 substrate
3 step
4 extended portion
11 fixed beam
12 substrate
13 concave portion
14 bridged portion
22 substrate
23 concave portion
24 metal catalyst film
25 CNT aggregate
26 liquid
27 CNT layer
S1 chemical vapor deposition step
S2 turn-down step
S3 density-increasing step
S4 removing step

### BEST MODE FOR CARRYING OUT THE INVENTION

An embodiment of the invention is to be described below specifically.

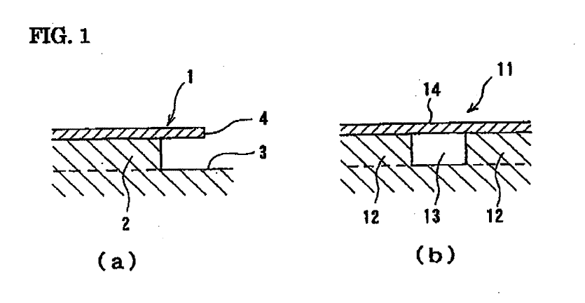

FIG. 1 schematically shows, in a cross sectional view, a typical structural example of one embodiment of a beam-like material according to the invention. FIG. 1(a) shows a beam-like material 1 of a cantilever type fixed at one end (hereinafter also referred to as a cantilever beam) and FIG. 1(b) is a beam-like material 11 of a fixed beam type fixed at both ends (hereinafter also referred to as a fixed-fixed beam). The cantilever beam 1 is a CNT aggregate comprising a plurality of CNTs aligned in the same direction in which one end is in contact with the surface of a substrate 2, the other end extends above a step 3 formed to the substrate 2, and the extended portion 4 is left free. Further, the fixed-fixed beam 11 is also constituted with the same CNT aggregate as in the cantilever beam 1, and bridged above a concave portion 13 formed in a substrate 12 in which both ends are in contract with the surface of the substrate 12 and a bridged portion 14 bridged above the concave portion 13 is left free.

Both of the beam-like materials 1, 11 are constituted with an aggregate comprising a plurality of CNTs aligned in one direction parallel with the surface of the substrates 2, 12. Accordingly, anisotropy can be provided for the physical properties such as electric properties, optical properties, and mechanical properties between the alignment direction of CNTs and the direction perpendicular thereto.

For the alignment direction of the CNTs, they can be aligned to any direction depending on the application use of the beam-like material. Since they show higher value for the bending strength required for general beams due to the anisotropy for the mechanical strength, it is typically preferred that they are aligned in the direction parallel with the longitudinal direction of both of the beam-like materials 1, 11 or the direction approximate thereto.

In the CNT aggregate constituting both of the beam-like materials 1, 11, since CNTs adjacent with each other are aligned, they are in a state intensely bonded by Van der Waals' force and the weight density thereof is 0.1 g/cm³ or more and, more preferably, 0.2 g/cm³ or more. In a case where the weight density of the CNTs in the CNT aggregate constituting both of the beam-like materials 1, 11 is more than the value described above, the CNTs are filled uniformly with no gaps, both of the beam-like materials 1, 11 exhibit a rigid state as a solid and can provide desired mechanical strength (elasticity, rigidity, etc.). On the contrary, in a case where the weight density of the CNTs is less than the value described above, a meaningful gap is formed between CNTs constituting the CNT aggregate. Therefore, the CNT aggregate no more forms a rigid solid, and no required mechanical strength can be obtained, as well as a chemical liquid, for example, a resist soaks into the gap between the CNTs upon applying known pattering technique and etching technique, making it difficult to form the beam-like material to a desired shape. In this case, higher weight density of the CNTs in the CNT aggregate is generally more preferred but the upper limit value thereof is about 1.5 g/cm³ from manufacturing restrictions.

The thickness, the width, and the length of both of the beam-like materials 1, 11 may be set properly depending on the application use and the cross sectional shape thereof may be in various shapes such as a rectangular, circular, elliptic, or polygonal shape. The size and the cross sectional shape of the beam-like material 1, U may be uniform or varied along the longitudinal direction.

The CNT of the CNT aggregate constituting both of the beam-like materials 1, 11 may be a single-walled CNT or multi-walled CNT. It can be decided as to which type of the CNT is used depending on the application use of both of the beam-like materials 1, 11. For example, in a case where high electric conductivity, flexibility, etc. are required, a single-walled CNT can be used and, in a case where importance is attached to rigidity, metallic property, etc., a multi-walled CNT can be used.

In the foregoings, it has been described that the beam-like material 1, 11 is disposed over the substrate 2, 12 having the step 3 or the concave portion 13. However, according to the invention, the beam-like material can be disposed so as to extend or bridge above a concave portion of an optional shape including a concave portion forming a cuboidal space, a substantially send-spherical space as in the inside of a dish, or a concave portion forming a space of a shape modified therefrom.

A method of manufacturing a beam-like material according to the invention is to be described below.

The method of manufacturing the beam-like material according to the invention includes each of the following steps:

### A. Chemical Vapor Deposition Step

A substrate formed with a metal catalyst film on the surface is used and a plurality of CNTs are grown by chemical vapor deposition (hereinafter referred to as CVD) in a predetermined direction crossing to the surface of the substrate from the metal catalyst film. The direction of growing the plurality of CNTs is generally in a direction perpendicular to the surface of the substrate but there is no particular restriction on the angle thereof so long as this is grown substantially in a predetermined direction.

### B. Turn-Down Step

A CNT aggregate comprising a plurality of the CNTs grown from the substrate is pulled up after dipped in a liquid, thereby turned down to the surface of the substrate.

### C. Density-Increasing Step

Density of the CNT aggregate is increased in a state of turned down to the surface of the substrate.

### D. Removing Step

A portion of the CNT aggregate increased in the density (unnecessary portion) is removed selectively.

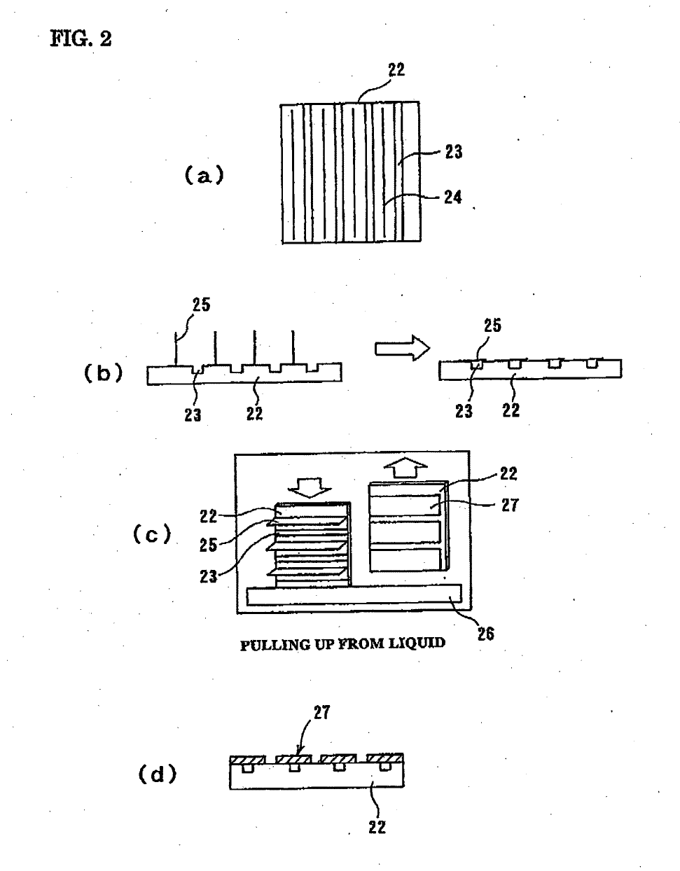

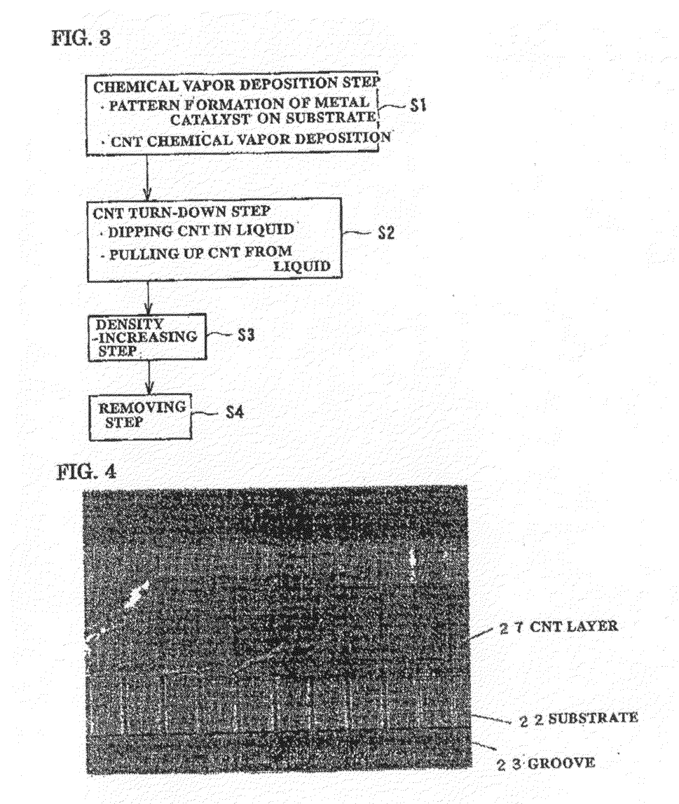

An example of the method of manufacturing the beam-like material according to the invention is to be described more specifically with reference to FIG. 2 and FIG. 3.

At first, in the chemical vapor deposition step (S1 in FIG. 3), a substrate 22 in which a straight grooved concave portion 23 and a metal catalyst film 24 of a linear pattern are formed in parallel with an appropriate distance between them is provided as shown in FIG. 2(a). Then, a plurality of CNTs are grown by CVD method from the metal catalyst film 24 in a predetermined direction crossing the surface of the substrate 22 (direction perpendicular to the substrate 22). In this embodiment, while the substrate 22 in which a plurality of the concave portions 23 and the metal catalyst film 24 of the linear pattern are formed in parallel with each other is shown as an example but the invention is not restricted thereto.

As the substrate 22 used for the chemical vapor deposition of the plurality of CNTs, various kinds of materials well-known so far can be used and, typically, a sheet material or a plate material having flat surface comprising metals such as iron, nickel, and chromium, oxides of the metals, or alloys thereof, non-metals such as silicon, quartz, and glass, or ceramics can be used.

As the metal catalyst film 24, appropriate metals actually used so far for the manufacture of the CNT can be used and the film can be formed by using well-known film forming techniques. Typically, metal thin films, for example, thin iron films, thin iron chloride films, thin iron-molybdenum films, thin alumina-iron films, thin alumina-cobalt films, thin alumina-iron-molybdenum films, etc. deposited by sputtering vapor deposition using masks can be illustrated.

The thickness of the metal catalyst film 24 may be set to an optimal value in accordance with the metal used as the catalyst and in a case, for example, of using the iron metal, it is preferably 0.1 nm or more and 100 nm or less.

The width of the metal catalyst film 24 can be set in accordance with a required thickness of a finally used beam-like material and it is set to a value of about 5 to 20 times the thickness of the beam-like material after increasing the density.

For the carbon compound as the feedstock material for the CNT in the CVD method, hydrocarbons, above all, lower hydrocarbons, for example, methane, ethane, propane, ethylene, propylene, acetylene, or a gas mixture thereof can be used suitably in the same manner as in the usual case.

The atmospheric gas for the reaction may be such one that does not react with the CNT and is inert at a growing temperature and includes, for example, helium, argon, hydrogen, nitrogen, neon, krypton, carbon dioxide, chlorine, or a gas mixture thereof.

Any atmospheric pressure for the reaction may be applied so long as it is within a pressure range where the CNTs have been manufactured so far, and it can be set to an appropriate value within a range, for example, from 10² Pa to 10⁷ Pa.

The temperature for the growing reaction in the CVD method is determined properly while considering the reaction pressure, the metal catalyst, the starting hydrocarbon source, etc., and the CNT can be grown satisfactorily in a range usually from 400 to 1200 (more preferably, 600 to 1000)° C.

Further, as the method of manufacturing the CNT aggregate, a method of growing a great amount of vertically aligned CNTs under the presence of a water content in a reaction atmosphere proposed previously by the same applicant of the invention (refer to Kenji Hata et al, Water-Assisted Highly Efficient Synthesis of Impurity-Free Single-Walled Carbon Nanotubes, SCIENCE, 2004, 11. 19, vol. 306, p. 1362-1364, or PCT/JP2008/51749 specification) could be used.

The CNT obtained by the method described above has excellent properties that the purity is 98 mass % or higher, the weight density is about 0.03 g/cm³, the specific surface area is from 600 to 1300 m³ (not-opened)/1600 to 2500 m³ (opened), the ratio for the extent of the anisotropy is 1:3 or more and 1:100 at the highest, and those applied with the turn-down and density-increasing steps are suitable for the applications as the beam-like material of the invention.

As the technique for obtaining the vertically aligned CNT aggregate applicable in the invention, various known methods can be used appropriately and, for example, a plasma CVD method (Guofang Zhong et al, Growth Kinetics of 0.5 cm Vertically Aligned Single-Walled Carbon Nanotubes, Journal of Physical Chemistry B, 2007, vol. 111, p. 1907 to 1910) may also be used.

In the next CNT turn-down step (step S2 in FIG. 3), the substrate 22 formed with the CNT aggregate 25 in the form of a film comprising a plurality of CNTs grown simultaneously in the same direction is entirely dipped in a liquid 26 and then pulled up at a predetermined velocity from the liquid 26. Then, as shown schematically in the drawing on the right of FIG. 2(b) and in the drawing on the right of FIG. 2(c), the CNT aggregate 25 is turned down on the substrate 22. Thus, the surface of the substrate 22 is covered with a plurality of the CNT aggregates 25.

As the liquid 26 for dipping, those having an affinity with the CNTs and with no remaining ingredient after evaporation are used preferably. For such liquid, water, alcohols (isopropyl alcohol, ethanol, methanol), acetones (acetone), hexane, toluene, cyclohexane, dimethylformamide (DMF), etc. can be used for instance. The dipping time in the liquid may be such that it is sufficient to wet the entire CNT aggregate 25 uniformly not leaving bubbles in the inside thereof.

As means for turning down the CNT aggregate 25 and increasing the density thereof, while a method of turning down the CNT aggregate 25 to the surface of the substrate 22 by press-contact of a roller or a press plate and then impregnating a liquid by using a spray or the like may also be considered. However, when the CNT aggregate 25 is turned down by pressing a solid, there occurs a disadvantage that a stress is concentrated locally to damage the CNTs or the CNT aggregate 25 is deposited entirely or partially adhered to the pressed solid and therefore, the method of dipping into the liquid 26 as described above is preferred.

In the next density-increasing step (Step S3 in FIG. 3), the density of the plurality of CNT aggregates 25 in a state turned down to the surface of the substrate 22 is increased to form a CNT layer 27 deposited to the surface of the substrate 22. The step is effected typically by drying the CNT aggregate 25 with deposition of the liquid 26. As the means for drying the CNT aggregate 25, spontaneous drying in a nitrogen atmosphere at a room temperature, drying in vacuum or heating in the presence of an inert gas such as argon can be used.

When the CNT aggregate 25 is dipped in the liquid 26, the CNTs adhere closely to each other and the entire volume shrinks, and the degree of adhesion is further enhanced upon vaporization of the liquid to considerably shrink the volume and, as a result, the CNT layer 27 with increased density is made. In this case, area shrinkage scarcely occurs at the surface parallel with the substrate 22 due to contact resistance with the substrate 22, and shrinkage occurs exclusively in the direction of the thickness of the CNT layer 27. Accordingly, the degree of alignment does not change before and after increasing of the density and the degree of alignment during growing remains as it is.

With each of the steps described above, a substrate 22 deposited with the CNT layer 27 comprising a plurality of CNT assemblies 25 aligned in one direction parallel with the surface of the substrate 22 is fabricated.

The main properties of the thus obtained CNT layer 27 are as described below.

CNT diameter: 1 to 5 nm (2.8 nm in average) single-walled CNT

Weight density: 0.1 to 1.5 g/cm³ (more preferably, 0.2 to 1.5 g/cm³)

Number density: 1.0×10¹² to 4.0×10¹³ N/cm²

Filling rate: 25 to 75%

Vicker's hardness: 5 to 100 Hv

In a case where the weight density of the CNTs in the CNT layer 27 formed as described above is within the range described above, a beam-like material of an optional shape can be formed easily, for example, by coating a resist on the CNT layer 27, drawing an arbitrary pattern to the resist by lithography, and etching an unnecessary portion of the CNT layer 27 using the resist as a mask. That is, this enables fabrication by applying well-known patterning technique and etching technique to the CNT layer 27 thereby enhancing the compatibility with an integrated circuit production process.

While the thickness of the CNT layer 27 can be set arbitrary to a desired value depending on the application use of the beam-like material, when it is 10 nm or more, integrity as the film can be maintained and electric conductivity required for providing a function as an electronic device or a device used for MEMS can be obtained. While there is no particular restriction on the upper limit value of the film thickness, it is preferably within a range about from 100 nm to 50 μm in a case of utilizing the same for a beam-like material as an object of the invention.

FIG. 4 shows an electron microscope photographic image of an example of a grooved substrate 22 deposited with the CNT layer 27 and FIG. 5 shows the electron microscope photographic image of FIG. 4 at a different magnification ratio.

In the next removing step (S4 in FIG. 3), a resist layer with a predetermined pattern is formed on the surface of the CNT layer 27, then a portion exposed from the resist layer in the CNT layer 27 is removed by etching and then the resist layer is removed. By the procedure, the cantilever beam 1 having a free end extended above the step 3 formed previously to the substrate 2 (FIG. 1-a), or the fixed-fixed beam 11 bridged above a concave portion 13 formed previously to the substrate 12 (FIG. 1-b) is manufactured.

In the manufacturing method described above, the substrate 22 on which the CNT aggregate 25 has been grown is used as it is for the substrate 2, 12 provided with the beam-like material 1, 11. In the invention, however, the substrate 2, 12 to be provided with the beam-like material 1, 11 may be provided as a second substrate (not illustrated) different from the substrate 22 on which the CNT aggregate 25 has been grown. In a case of providing the beam-like material to the second substrate, the CNT aggregate 25 that has been aligned vertically and grown to a film shape may be detached from the surface of the substrate 22 for growing, exposing the same to a liquid and then placing the same to the surface of the second substrate with the axis of alignment being parallel with the surface of the second substrate, or a film-shaped CNT aggregate 25 detached from the substrate 22 for growing may be placed on the surface of the second substrate with the axis of alignment thereof being parallel with the surface of the second substrate, exposed in this state in a liquid and then dried. In this case, the turn-down step described above (S2 in FIG. 3) may be replaced with a step of placing the CNT aggregate 25 detached from the substrate 22 for growing to the surface of the second substrate. Needless to say, a step or a concave portion may be previously formed as required to the second substrate.

The density-increasing step effected by drying the CNT aggregate 25 exposed to the liquid in a state being placed on the surface of the second substrate, and the removing step effected by forming a resist layer of a predetermined pattern to the surface of the CNT layer increased in the density on the surface of the second substrate, then removing a portion exposed through the resist layer in the CNT layer by etching, and then removing the resist layer are basically identical with those in the manufacturing step described above.

### EXAMPLE

Examples are shown below and the invention is to be described specifically. It will be apparent that the invention is not restricted only to the following examples.

### Example 1

At first, description is to be made for an example in which a substrate for growing a CNT aggregate and a substrate for forming a beam-like material are identical.

A groove of 10 μm depth, 10 μm width, and 50 μm of length was formed to a silicon substrate having an oxide film of 100 nm thickness by a well-known reactive ion etching method to prepare a grooved substrate.

An iron metal catalyst film of a linear pattern with 1 nm thickness, 4 μm width, and 30 μm length was deposited at a position along the groove on the substrate by using a well-known sputtering vapor deposition method, and a CNT aggregate was grown on the substrate by a known CVD method under the following conditions.

Feedstock gas: ethylene; feed rate: 1000 sccm

Atmospheric gas: helium-hydrogen gas mixture; feed rate: 1000 sccm

Pressure: 1 atm

Water content (existent amount): 150 ppm

Reaction temperature: 750° C.

Reaction time: 10 min

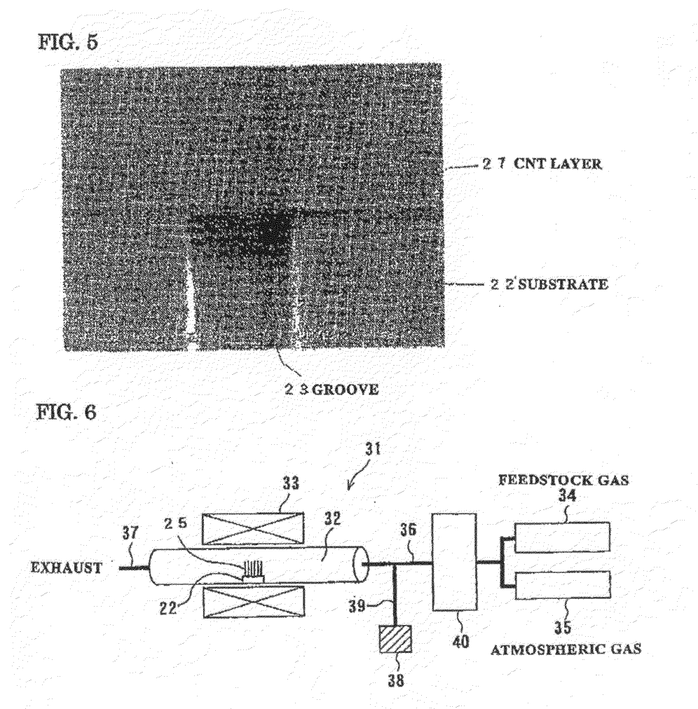

FIG. 6 shows an example of a CVD apparatus used for the manufacture of a CNT aggregate applied to this example. A CVD apparatus 31 includes a tubular reaction chamber 32 comprising quartz glass (1 inch diameter) for accommodating a substrate 22 carrying a metal catalyst thereon, a heating coil 33 disposed so as to externally surround the reaction chamber 32, a supply pipe 36 connected to one end of the reaction chamber 32 for supplying a feedstock gas 34 and an atmospheric gas 35, an exhaust pipe 37 connected to the other end of the reaction chamber 32, and a steam supply pipe 39 connected to an intermediate portion of the supply pipe 36 for supplying steams 38 together with a carrier gas not illustrated in the drawing. Further, for supplying an extremely small amount of steams at a high control accuracy, a purification device 40 for removing oxide materials from the feedstock gas 34 and the atmospheric gas 35 is provided additionally to the supply pipe 36 for the feedstock gas and the atmospheric gas. Although not illustrated, a control device including a flow rate control valve or a pressure control valve is disposed at an appropriate position. The CVD apparatus capable of manufacturing the CNT aggregate applicable to the invention is not restricted only to the constitution illustrated above.

The steams to be in contact together with the feedstock gas to the metal catalyst film 24 of the substrate 22 have an effect of improving the activity of the catalyst or extending the working life of the catalyst by adding them into the growing atmosphere of the CNT and, as a result, can efficiently grow the CNT. The mechanism for such a function of the steams is considered as below. That is, in the CNT synthesis method not containing steams, fine catalyst particles are instantly covered with the carbon film and deactivated. On the contrary, according to the CNT synthesis method of incorporating the steams in the atmosphere, it is considered that when steam are in contact with the catalyst film 24, the steams remove the carbon film covering the fine catalyst particle to clean the base surface of the catalyst and, as a result, activate the catalyst.

The material having such a function is generally any material containing oxygen, which may develop the function described above without giving damages to the CNT at a growing temperature. In addition to the steams, oxygen-containing compounds of lower number of carbon atoms, for example, alcohols such as methanol and ethanol, ethers such as tetrahydrofuran, ketones such as acetone, aldehyde, acids, esters, hydrogen nitride, carbon monoxide, and carbon dioxide may also be used depending on the reaction conditions.

Further, before the supply of the feedstock gas, a reducing gas may be preferably mixed in the atmospheric gas and in contact with the metal catalyst film 24 for a predetermined time. This finely particulates the metal catalyst present in the metal catalyst film 24 and prepares a metal catalyst in a state conforming to the growing, for example, of the single-walled CNT. In this case, by selecting an appropriate thickness for the metal catalyst film and reducing reaction conditions, fine catalyst particles with a diameter of several nanometers can be adjusted to the density of from 1.0×10¹¹ to 1.0×10¹³ (N/cm²). The density is suitable to the growing of a plurality of CNTs aligned in the direction perpendicular to the catalyst film forming surface of the substrate. The reducing gas may be any gas that can act on the metal catalyst and promote fine particulation in a state conforming to the growing of the CNT and, for example, a hydrogen gas and ammonia, or a gas mixture thereof can be used.

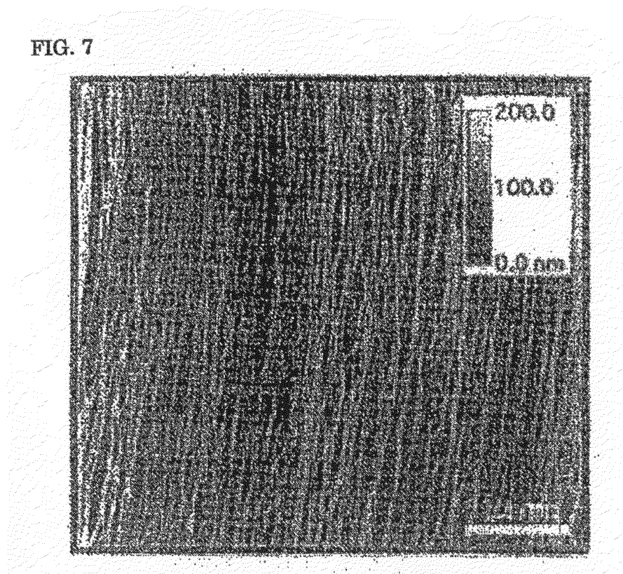

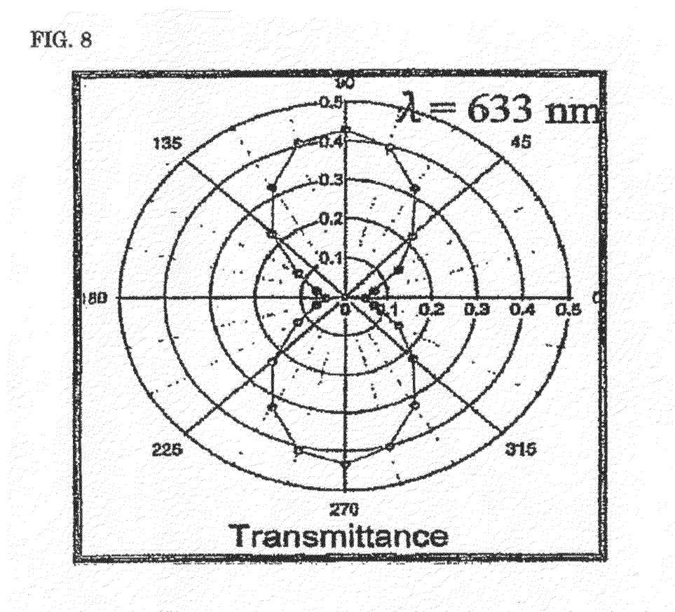

Thus, a CNT layer of a predetermined thickness increased in the density was deposited on the groove of the substrate by dipping the substrate 22 on which the vertically aligned CNT aggregate 25 was grown into the liquid 26 (for example, isopropyl alcohol, hereinafter referred to as IPA) for 10 sec, then pulling up at a predetermined speed and spontaneously drying the same in a nitrogen atmosphere at a room temperature. The sheet-like CNT aggregate having 4 μm thickness just after the synthesis was compressed to 250 nm thickness when pulled up from IPA and dried. The situation is shown in FIG. 7 by a scanning type atomic force microscope photographic image. It can be seen from FIG. 7 that the CNT aggregate is at a high density and has excellent alignment. The same effect was obtained also by using ethanol, methanol or acetone in addition to IPA used herein.

FIG. 8 shows an example for the measurement of optical transmittance as an example of the anisotropy of a CNT aggregate applied to the beam-like material of the invention. It can be seen from FIG. 8 that when the angle relative to the direction of alignment is different, the transmittance changes to develop anisotropy.

The CNT layer in this example had a film thickness of 250 nm, a weight density of 0.464 g/cm³, a number density of CNT of 8.0×10¹² N/cm², a filling rate of 50%, a Vickers hardness of 7 Hv, a specific surface area of 1000 m²/g, and a purity of 99.98 mass %.

Then, a resist (HSQ) (FOX16/manufactured by Dow Corning Corporation) was coated to the CNT layer formed as described above by a spin coating method and baked at 90° C. for 10 min. Since FOX 16 is soaked into the CNT layer 27 when it is coated directly to the CNT layer 27, it is preferred to apply a primer treatment (coating a 5-fold diluted solution of PMMA 495/manufactured by Microchem Corporation by a spin coating method and baking at 180° C. for one min). In a case where the CNT layer is extremely thin, or a span required for the beam-like material is large, it is preferred to use a resist having a specific gravity as small as possible in order to avoid that the CNT layer is distorted due to the weight of the resist.

Then, a stripe-like pattern of an appropriate width was drawn to a resist coating film by an electron beam drawing apparatus (CABL 8000/manufactured by Crestec Corporation), which was developed by an aqueous solution of tetramethyl ammonium hydroxide (2.38%, ZTMA-100/manufactured by Zeon Corporation) to form a mask. A portion exposed from the mask of the CNT layer 27, that is, an unnecessary portion was removed by a reactive ion etching apparatus (RIE-200L/manufactured by Samco Inc.), while supplying O₂ and Ar. Specifically, after applying etching under the condition at O₂; 80 W, 10 sccm, 7 min, etching was applied under the condition of 80 W, 10 Pa and 3 min while supplying O₂ and Ar simultaneously each at 10 sccm. Then, naps of CNT were removed clearly by introduction of Ar to obtain a sharp edge.

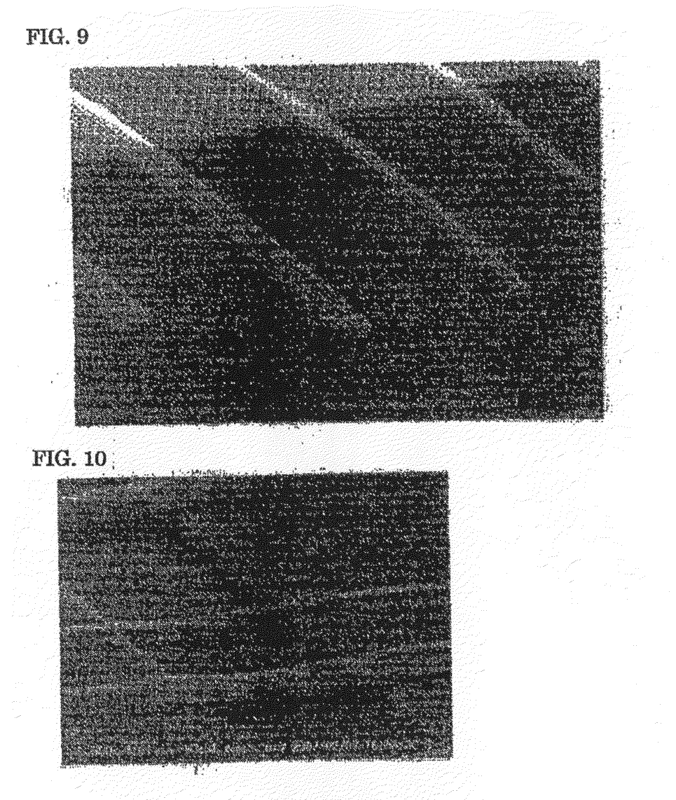

Finally, by removing the mask of FOX 16 with buffered hydrofluoric acid (4.7% RF, 36.2% NH₄F, 59.1% H₂O/manufactured by Morita Chemical Industries Co. Ltd.), and the mask of PMMA 495 by a releasing agent (remover PG/manufactured by Microchem Corporation) respectively, and cleaning with IPA or the like, a cantilever beam model shown in FIG. 9 and a fixed beam model shown in FIG. 10 were obtained. The dimension of the model was as described below.

Thickness: 250 nm

Length: cantilever beam/2 μm, 5 μm, 7 μm, and fixed-fixed beam/10 μm

Width: 2 μm, 5 μm

Cross sectional shape: Rectangular

CNT type: single-walled

In a case where a desired beam-like material is fine, since the beam-like material may possibly be deformed by a surface tension exerting at the boundary with the CNT layer upon evaporation of the cleaning liquid, supercritical drying is applied preferably.

From the foregoings, it has been found that the beam-like material of the invention can be manufactured by applying well-known patterning technique and etching technique.

### Example 2

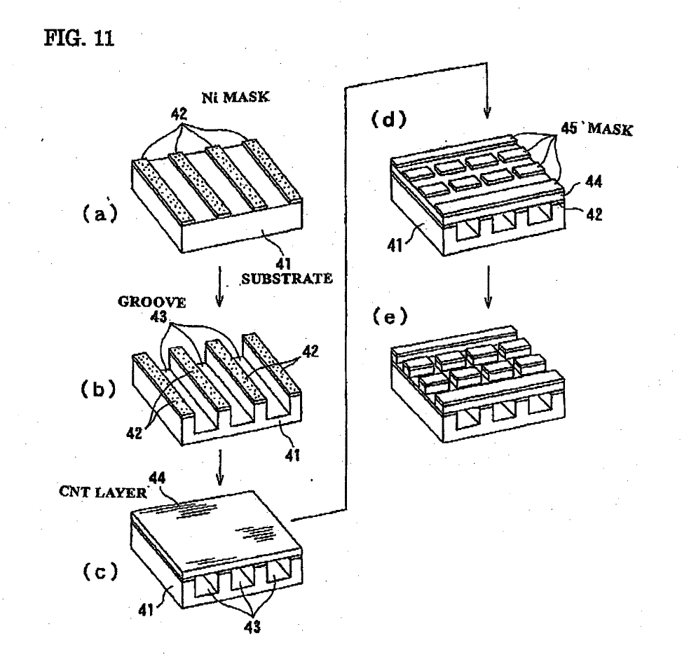

Then, a manufacturing method of forming a beam-like material by depositing a CNT aggregate obtained by the chemical vapor deposition step to a second substrate different from the substrate used for the chemical vapor deposition step is described with reference to FIG. 11.

A silicon substrate 41 with an oxide film of 500 nm was provided as a second substrate and, after supersonically cleaning the surface thereof with IPA, O₂ plasmas were irradiated at 300 W for 1 min for cleaning and then a resist (ZEP-520A/manufactured by Zeon Corporation) was coated by a spin coating method and baked at 150° C. for 3 min.

Then, a groove (or step) was patterned to the resist layer using an electron beam drawing apparatus (CABL 8000/manufactured by Crestec Corporation), which was developed by using a developer (ZED-N50/manufactured by Zeon corporation) to form a mask for a portion to form a groove. Then, after vapor depositing Ni by sputtering to a thickness of 100 nm to a portion exposed from the mask, the resist was removed by a stripping solution (ZDMAC/manufactured by Zeon Corporation), and rinsed with IPA. As described above, a silicon substrate 41 masked with an Ni layer 42 for a portion of the surface was obtained (FIG. 11-a).

The surface of the silicon substrate 41 with the Ni layer mask was cleaned by O₂ plasmas and the silicon substrate 41 was etched together with the oxide film by using the pattern of the Ni layer 42 as a mask by a reactive ion etching apparatus (RIE-200L/manufactured by Samco Inc.) while supplying CHF₃, SF₆, and O₂ (CHF₃: 100 W, 8.5 Pa, 40 sccm, 45 min/SF₆: 100 W, 8.5 Pa, 60 sccm, 45 min/O₂: 100 W, 8.5 Pa, 55 sccm, 45 min), and etching the silicon substrate 41 to form a groove 42 (FIG. 11-b). Specifically, etching was applied under the conditions at 100 W, 8.5 Pa, 45 min in a state of supplying CHF₃, SF₆, and O₃ simultaneously at 40 sccm, 60 sccm, and 55 sccm respectively.

A film-shaped CNT aggregate prepared by a separate step was placed on the surface of the silicon substrate 41 fabricated as described above, which was exposed uniformly to IPA and baked and dried at 180° C. in vacuum for 10 min. By the procedure, the CNT aggregate was increased in the density and bonded closely to the surface of the silicon substrate 41 to obtain a silicon substrate 41 formed with the CNT layer 44 at the surface (FIG. 11-c). The weight density of the CNT layer 44 was 0.464 g/cm³. The Ni layer 42 remaining on the surface of the silicon substrate 41 has an effect of further enhancing the adhesion of the CNT layer 44.

Then, FOX 16 and PMMA495 were coated by a spin coating method to the CNT layer 44 deposited to the surface of the silicon substrate 41, and baked to form a resist layer in the same manner as in the first example described above, and a mask 45 of a predetermined pattern was formed in the same manner as in the first example by the resist layer (FIG. 11-d). Then, an unnecessary portion exposed from the mask 45 of the CNT layer 44 was removed by a reactive ion etching apparatus (FIG. 11-e).

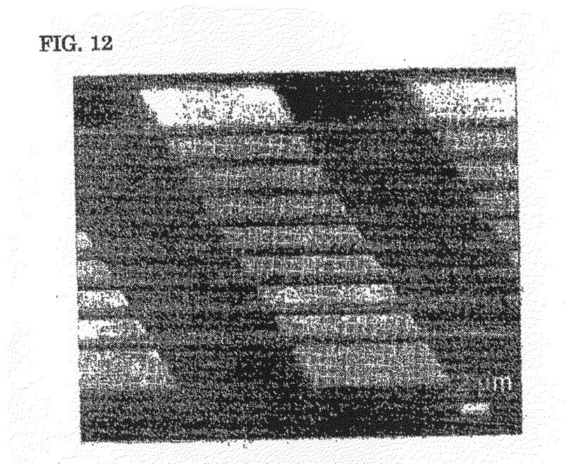

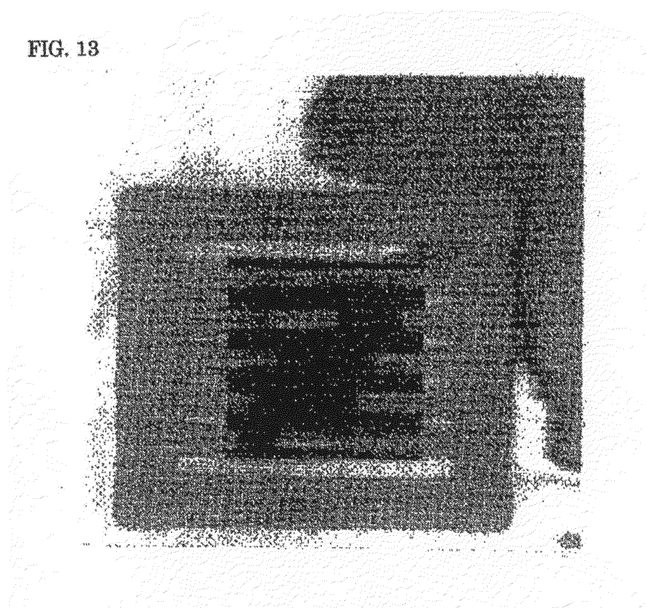

Finally, the mask 45 was removed and cleaning was applied thereby obtaining a model of a beam-like CNT material of a fixed-fixed beam type and a cantilever beam type not causing sagging or the like to the portion extended above the groove as shown in FIG. 12. The model had a dimension as described below.

Thickness: 250 nm

Length: cantilever beam/1 to 7 μm (each apart by 1 μm), and fixed-fixed beam/10 μm

Width: 2 μm

Cross sectional shape: Rectangular

CNT type: single-wailed

In view of the foregoings, it has been found that the beam-like material of the invention can be manufactured by applying the well-known patterning technique and etching technique to the CNT layer transferred to the second substrate different from the substrate for growing.

### Example 3

Then, another example of a manufacturing method of forming a beam-like material from a CNT layer deposited to a second substrate which is different from the substrate for growing used in the chemical vapor deposition step is to be described.

At first, a silicon substrate (second substrate) having an oxide film of 500 nm thickness at the surface was covered at the rear face (surface with no oxide film) thereof with a resist mask (ZEP-512A) while leaving a 200 μm length square hole, which was dipped in CsOH over one night to wet etch the rear face of the silicon substrate. By the procedure, a portion for 200 μm square in the silicon substrate was removed while leaving only the oxide film of 500 nm thickness.

Then, by placing the CNT aggregate prepared in a separate step on the surface of the silicon substrate, that is, on the oxide film and applying a density-increasing treatment by the same method as in Example 2, a CNT layer at a thickness of 250 nm and with a weight density of 0.464 g/cm³ was deposited to a portion for the 200 μm square hole formed by wet etching on the surface of the silicon substrate (on the oxide film). Further, an unnecessary portion of the CNT layer was removed by using the lithographic technique and reactive ion etching technique by the same method as in Example 2. In this case, since the oxide film was present below the CNT layer, it was different from Example 2 in that only FOX 16 was used for the resist and PMMA 495 was not used.

Finally, by removing the oxide film of 500 nm thickness and the resist FOX 16 by hydrofluoric acid vapors, a fixed-fixed beam type beam-like material bridging over opposed inner edges of a 200 μm length square hole (central portion appearing black) (one at the uppermost position in FIG. 13) and cantilever beam-like materials extending toward the inside of the square hole were obtained as shown in FIG. 13.

The size of the beam-like materials was as described below.

Thickness: 250 nm

Length: cantilever beam/10 to 60 μm (each apart by 10 μm), 110 μm, and 150 μm, and fixed-fixed beam/200 μm

Width: 20 μm

CNT type: single-walled

According to the method, since the deformation of the CNT layer is restricted by the oxide film remaining on the surface of the silicon substrate, the fine beam-like material has no possibility of undergoing deformation also in a case of a fixed-fixed beam of a large span, or a cantilever beam with large amount of extension, even when an external force exerts during the etching step of the CNT layer.

### Example 4

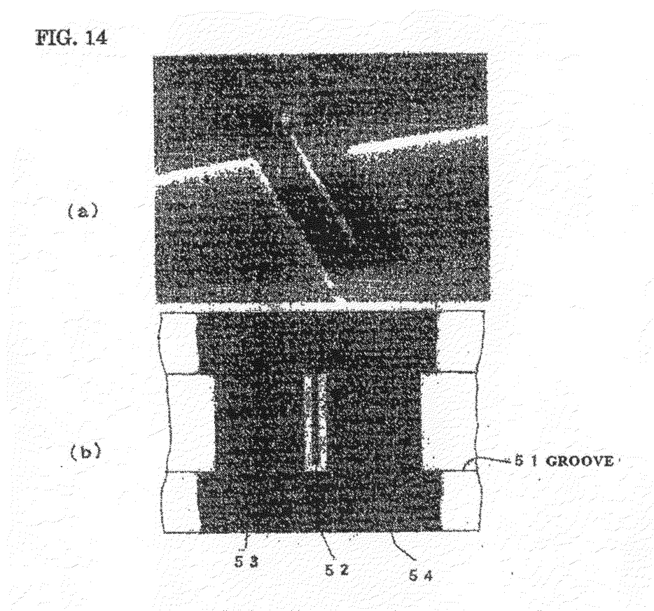

As a specific example formed by applying the invention as has been described above specifically, FIG. 14 shows a horizontal operation type 2-terminal switch having a cantilevered beam-type movable electrode 52 extending from the CNT layer deposited to the substrate so as to cover a portion above the groove formed previously to the substrate to a portion above the groove 51, and fixed electrodes 53, 54 arranged at an appropriate gap on both right and left sides of the movable electrode 52 respectively. The extending length of the movable electrode 52 was 2.5 μm and the gap between the movable electrode 52 and the fixed electrodes 53, 54 is 750 nm.

### Validation Example 1

It is to be shown below that the physical properties of the beam-like material according to the invention can be controlled depend on the shape with reference to the beam-like material manufactured by the same method as in Example 1.

Specification of cantilever beam
Thickness: 250 nm
Weight density: 0.464 g/cm³
Length: 10, 20, 30, 70 μm
Width: 10 μm

Specification of fixed-fixed beam
Thickness: 310 nm
Weight density: 0.374 g/cm³
Length: 30, 40 μm
Width: 10 μm

For a plurality of the beam-like materials having length different from each other, the resonance frequency was measured by a vibrational detection method due to vibrations under heating and laser reflection of the beam-like material by pulse laser (refer to B. Ilic, S. Krylov, K. Aubin, R. Reichenbach, and H. G. Craighead, “Optical excitation of nanoelectromechanical oscillators”, Appl. Phys. Lett. 86, 193114 (2005). As a result, as shown in FIG. 15, it has been found that the resonance frequency of the beam-like CNT material of the invention tended to be higher as the size of the length was smaller. The relation between the length and the resonance frequency of the beam-like material well agrees with the theoretical value curve of a resilient material drawn in FIG. 15 both for the cantilever beam and the fixed-fixed beam (fine line for fixed beam, thick line for cantilever beam). The theoretical value curve is derived from theoretical formula attached on the lower right in FIG. 15 (f: resonance frequency, t: thickness, L: length, E: Young's modulus, p: density) assuming E and ρ as fitting coefficients.

The result shows that the resonance frequency, that is, the dynamic property of the beam-like CNT material of the invention depends on the shape, that is, can be controlled by the shape. Further, the result shows that the beam-like material of the invention can oscillate periodically and this shows that the beam-like CNT material of the invention functions as an elastic body, that is, has shape retainability and shape restorability.

A table attached on the upper right in FIG. 15 shows a sound velocity as one of indexes representing the dynamic property of a material. It can be said that a material showing a high sound velocity is a material which is light in the weight and tough and suitable to a mechanical element, for example, an MEMS device. According to the result of measurement, the sound velocity in the beam-like CNT material of the invention obtained based on the fitting coefficient shows a value equal with or larger than the value compared with the reported property which is the highest value of a single crystal silicon (Si) in the (111) direction of the crystallographic direction and shows that the beam-like CNT material of the invention is extremely suitable, for example, to MEMS devices, etc.

### Validation Example 2

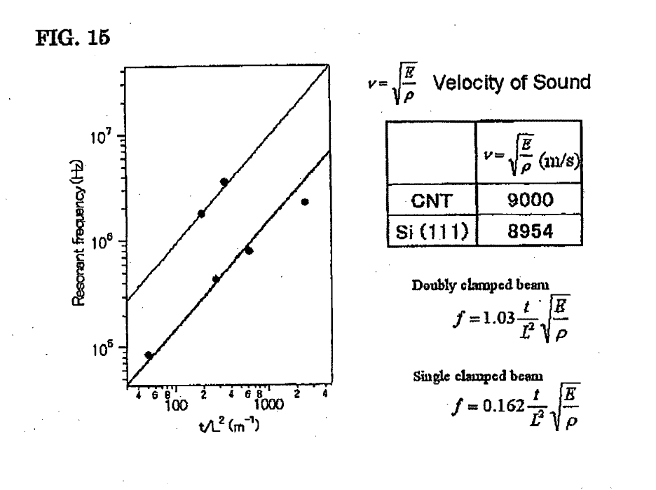

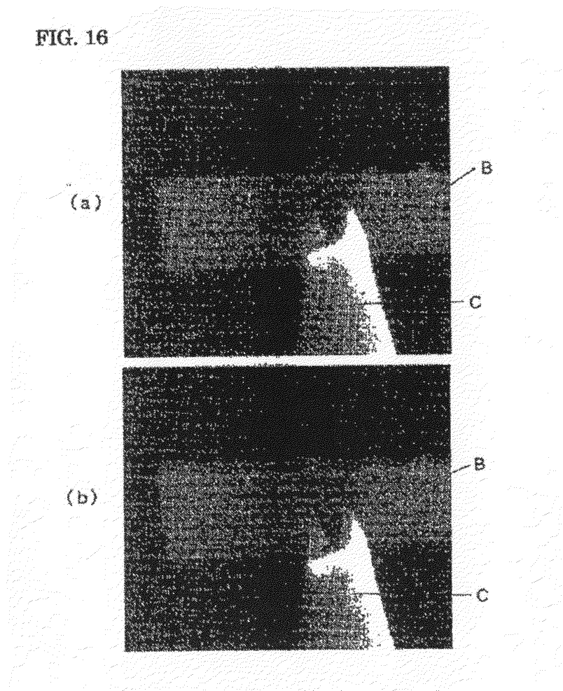

FIG. 16 shows that the beam-like CNT material of the invention functions as an integral elastic material and an electric conductor and, further, has shape retainability and shape restorability. Specifically, a probe electrode C made of tungsten was brought closer to a distance of 500 nm to a cantilever beam-type beam-like CNT material B having a length of 60 μm, a width of 10 μm, a thickness of 230 nm, and a weight density of 0.504 g/cm³ and rested, and the situation of displacement of the beam-like CNT material B caused by electrostatic attraction was observed by a scanning type electron microscope (Hitachi 4300) by applying a voltage of about 5 V.

As a result, the beam-like CNT material B drawn by electrostatic attraction was brought into contact with the probe electrode C as shown by the photograph on the upper side of FIG. 16 and, when the application voltage was lowered to 0V, it receded from the probe electrode C and returned to the original state as shown by the photograph on the lower side of FIG. 16.

In view of the result, it has been found that the beam-like CNT material of the invention as an integral elastic body and an electronic conductor can be in contact with or recede from the probe electrode. Further, since the beam-like CNT material retains the original shape when receding from the probe electrode, it has been found that the material has shape retainability and shape restorability.

### Validation Example 3

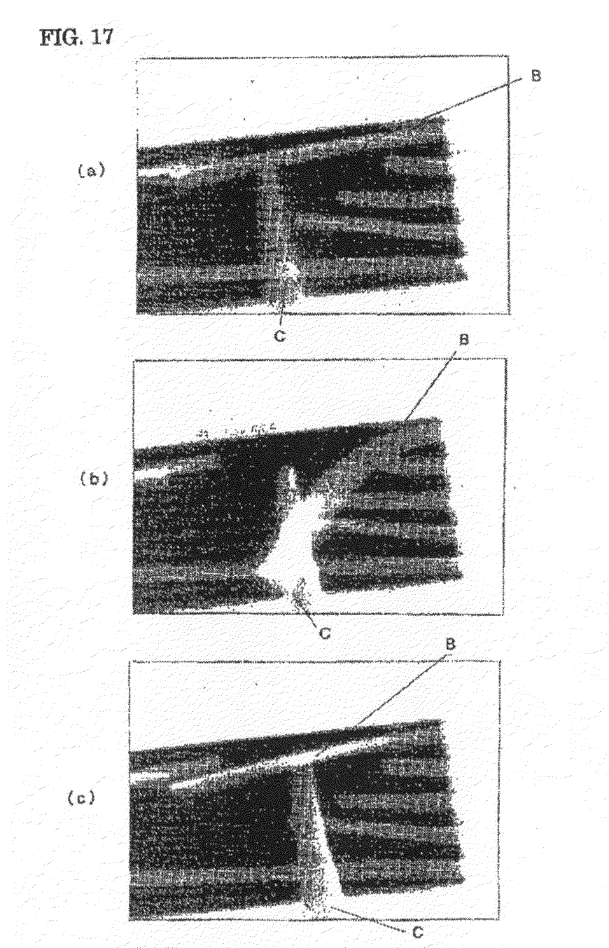

FIG. 17 is an electron microscope photographic image for validating the extent of flexibility and shape retainability of the beam-like CNT material B by displacing a probe electrode C that is put against the free end of the cantilever type beam-like CNT material B described above and observing the bending state of the beam-like CNT material B that undergoes an external force in a stepwise manner. As illustrated distinctly in FIG. 17, the beam-like CNT material B is distorted without breaking no flexure to possess a shape as an integral beam-like material even when an external force is applied. The result shows that since the beam-like CNT material of the invention is an aggregate of CNT having high density and aligned in one direction, this functions effectively for obtaining high shape retainability.

### Validation Example 4

The followings show a result of validating the controllability of the film thickness and the weight density before and after the density-increasing treatment in the density-increasing step of the invention. As experimental conditions therefor, for obtaining a desired number of film-shaped CNT aggregates of a desired film thickness, the width of the metal catalyst served to the chemical vapor deposition step (film thickness before increasing the density) was set as: two sets for 1 μm, 1 set for 2 μm, 2 sets for 4 μm, and 4 sets for 7.5 μm.

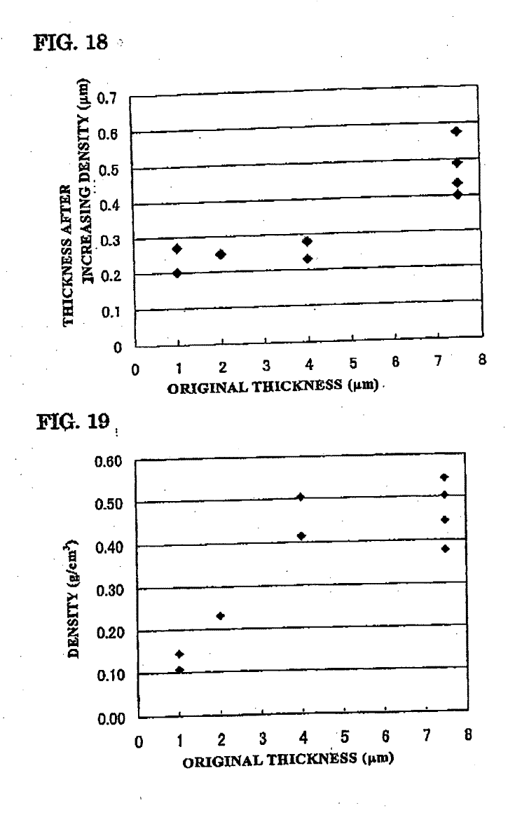

The result is to be described below with reference to FIGS. 18 and 19. As shown in FIG. 18 (relation graph between the original film thickness and the film thickness after increasing the density), the film-shaped CNT aggregate having a film thickness of 7.5 μm before increasing the density shrinks to about 0.5 μm in average after increasing the density, whereas the film-shaped CNT aggregate having 1, 2, 4 μm of film thickness before increasing the density shrinks to 0.2 μm to 0.3 μm after increasing the density. This shows that the CNT film after increasing the density has different density depending on the film thickness before increasing the density.

On the other hand, since the weight of the film-shaped CNT aggregate before increasing the density is extremely small, measurement for the weight density is difficult. In view of the above, the weight density of the film-shaped CNT aggregate before increasing the density is estimated based on the density of a bulk CNT aggregate grown from a substrate on which a metal catalyst film has been deposited over the entire surface without applying linear patterning.

In this case, the density of the bulk CNT aggregate is calculated based on weight/volume and it has been known that the density of a bulk CNT aggregate is constant under various conditions. For example, it is reported in the Non-Patent Document (Don N. Futaba, et al, 84% Catalyst Activity of Water-Assisted Growth of Single Walled Carbon Nanotube Forest Characterization by a Statistical and Macroscopic Approach, Journal of Physical Chemistry B, 2006, vol. 110, p. 8035-8038) that the weight density of the bulk CNT aggregate shows a constant value (0.029 g/cm³) for the height of the aggregate from 200 μm to 1 mm. That is, it can be estimated that the density of the film-shaped CNT aggregate grown under the growing conditions and using the catalyst substantially identical with those for the growing of the bulk CNT aggregate is not different greatly from the density of the bulk CNT aggregate.

When the compression ratio for the film-shaped CNT aggregate in the density-increasing step is defined as: (compression ratio=original thickness÷thickness after increasing the density), the weight density of the film-shaped CNT aggregate after increasing the density is: (CNT density=compression ratio×0.029 g/cm³). When the weight density of the film-shaped CNT aggregate at each thickness after increasing the density is derived based thereon, this gives a relation as shown in FIG. 19. In this validation example, the weight density could be controlled from 0.11 g/cm³ to 0.54 g/cm³ by controlling the film thickness.

Also in the film-shaped CNT aggregate obtained as described above having the weight density of 0.11 g/cm³, close bondability with the substrate is kept sufficiently, and the same patterning as in each of the examples was possible. On the contrary, in a case of the film-shaped CNT aggregate before the density-increasing treatment (weight density: 0.029 g/cm³), application of the known etching and lithographic techniques was substantially impossible because of insufficient close bondability with the substrate or corrosion of the resist.

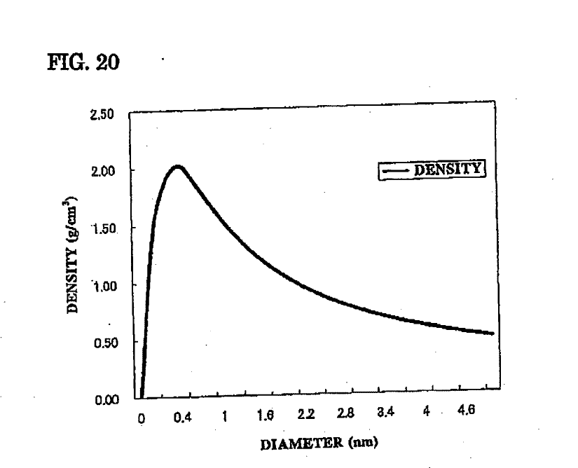

The upper limit for the weight density of the film-shaped CNT aggregate controllable in the invention is not restricted to 0.54 g/cm³ used in the validation example. Although not described positively in the present specification, it is possible, in principle, to attain a weight density within a further wide range by controlling the diameter of the CNT. Assuming that all CNTs have an identical diameter and all CNTs are closest packed by the density-increasing step, it can be easily calculated that the CNT density after increasing the density is increased as the diametrical size of the CNT decreases (refer to FIG. 20). The average diameter for the CNTs in the film-shaped CNT aggregate used in the examples described above is about 2.8 nm and when it is assumed that the CNTs are closest packed in this case, the weight density is about 0.78 g/cm³ as shown in FIG. 20. In this regard, it has already been known that the diameter for the CNT can be made further smaller (about 1.0 nm) by utilizing the technique reported in a non-patent document (Ya-Qiong Xu, et al, Vertical Array Growth of Small Diameter Single-Walled Carbon Nanotubes, J. Am. Chem. Soc., 128(20), 6560 to 6561, 2006). In view of the above, it is considered that the weight density can be increased to about 1.5 g/cm³ at the maximum by reducing the diameter of the CNT.

1. A beam-like material comprising a plurality of carbon nanotubes and formed of carbon nanotube aggregates including the plurality of carbon nanotubes aligned in the same direction and having a weight density thereof from 0.1 to 1.5 g/cm³.

2. A method of manufacturing a beam-like material comprising a plurality of carbon nanotubes, including;
a chemical vapor deposition step of using a substrate on the surface of which a pattern of a metal catalyst is formed and growing the plurality of carbon nanotubes by chemical vapor deposition in the same identical direction from the pattern of the metal catalyst,
a turn-down step of turning down the carbon nanotube aggregate comprising a plurality of carbon nanotubes aligned in the same direction to the surface of the substrate,
a density-increasing step of increasing the density of the carbon nanotube aggregate turned down to the surface of the substrate such that the weight density thereof is from 0.1 to 1.5 g/cm³, and
a removing step of selectively removing an unnecessary portion of the carbon nanotube aggregate increased in the density.

3. A manufacturing method of a beam-like material according to claim 2, wherein the turn-down step is a step of pulling up the carbon nanotube aggregate after dipping the same in a liquid thereby turning down the same to the surface of the substrate, and the density-increasing step is a step of drying the carbon nanotube aggregate after the turn-down step.

4. A manufacturing method of a beam-like material comprising a plurality of carbon nanotubes, including:
a chemical vapor deposition step of using a substrate on the surface of which a pattern of a metal catalyst is formed and growing the plurality of carbon nanotubes by chemical vapor deposition in the same direction from the pattern of the metal catalyst,
a placing step of placing a carbon nanotube aggregate comprising the plurality of carbon nanotubes aligned in the same direction to the surface of a second substrate with the axis of alignment being parallel with the surface of the second substrate,
a density-increasing step of increasing the density of the carbon nanotube aggregate placed on the surface of the second substrate such that the weigh density is from 0.1 to 1.5 g/cm³, and
a removing step of selectively removing an unnecessary portion of the carbon nanotube aggregate increased in the density.

5. A manufacturing method of a beam-like material according to claim 4, wherein the density-increasing step is a step of exposing the carbon nanotube aggregate to a liquid and drying the same in a state being placed on the second substrate.
